(19) United States
(12) Patent Application Publication
(10) Pub. No.: US 2026/0173804 A1
(43) Pub. Date: Jun. 18, 2026

(54) DEVICE FOR HOLDING, POSITIONING AND/OR MOVING AN OBJECT IN A VACUUM

(71) Applicant: VACOM Vakuum Komponenten & Messtechnik GmbH, Großlöbichau (DE)

(72) Inventors: Klaus Bergner, Bad Köstritz (DE); Sally Händschel, Bucha (DE); Viachaslau Pratsenka, Jena (DE)

(21) Appl. No.: 18/868,223

(22) PCT Filed: Oct. 10, 2023
(86) PCT No.: PCT/EP2023/078033

§ 371 Date: Nov. 22, 2024

(30) Foreign Application Priority Data
Oct. 12, 2022 (DE) 10 2022 126 599.4
Nov. 23, 2022 (DE) 10 2022 130 959.2

(51) Int. Cl. H10P 72/50; H10P 72/76

(52) U.S. Cl. CPC H10P 72/50; H10P 72/7602

(57) ABSTRACT

The invention consists of a device for holding, positioning and/or moving an object in a vacuum and comprises a base, an end effector with substrate holder, a linear drive coupled to the end effector via a carriage, optionally a vertical or lifting drive acting on the base and a magnetic bearing for the carriage. In accordance with the invention, the linear drive is designed as a fluid-actuated, otherwise closed cylinder with a double-acting piston, wherein the piston is provided with a magnet arrangement. The carriage has a magnetic ring which engages around the cylinder at least at a distance on the outside and which surrounds the cylinder without contact.

The invention relates to a device for holding, positioning and/or moving an object in a vacuum, comprising a base, an end effector with substrate holder, a linear drive coupled to the end effector via a carriage, a vertical or lifting drive engaging the base and a magnetic bearing for the carriage according to the preamble of claim 1.

For example, when processing substrates for the production of semiconductor components, large substrates are used that have to undergo various surface treatment procedures.

For example, a coating must be applied, exposure and etching steps or diffusion processes are required.

The majority of surface treatment processes must be carried out under clean room conditions or in a vacuum.

Structures down to the nanometer range have to be formed from substrates for modern semiconductor components, which requires extremely precise feeding and positioning of these substrates.

Furthermore, the necessary absence of particles in the substrate environment places high demands on the corresponding manipulators.

For this reason, contact-free mounting of the substrate and the design of a corresponding holding, movement or traversing drive is necessary.

Air bearings for high-purity production environments are well known here, although these pose a problem for the treatment steps to be carried out due to air currents in the vicinity of the substrate.

Magnetic holding or positioning devices having a base and an object-supporting carrier are also known.

In many cases, several magnetic bearings, each with a distance sensor and a control circuit, are provided for contactless mounting of the carrier on the base, which keep the carrier in a floating state at a predetermined distance from the base.

Likewise known solutions for a non-contact bearing of a carrier to be moved along a stationary base for holding a substrate can have several individual or discrete magnetic bearings spaced apart in a transport direction.

For the movement of the carrier along a series of magnetic bearings, it is necessary that the magnetic bearings arranged stationary on the base interact mechanically with the carrier depending on the current position of the carrier during the transport movement of the carrier.

Lateral or transverse guide means must also be provided for contactless mounting and contactless transportation of a carrier along a travel path specified by the base. These can be realized by means of appropriately configured magnetic bearings.

Linear motors or linear actuators are known as drives for contactless transportation and for the corresponding movement of the carrier along the base. One such linear drive is the subject matter of DE 10 2010 045 437A1. The linear drive consists of a housing with an end plate and an end plate and a piston arranged movably inside the housing and guided by a piston rod. The end plate, which is firmly connected to the housing, has a central guide for a first medium, which extends into the interior of the housing. The end plate or the housing has a means for discharging the first fluid medium and means for supplying and discharging a second fluid medium.

EP 2 346 148 A1 discloses a linear drive for a rotary stroke motor. Such a drive comprises a winding system with a plurality of wound coils, which are arranged coaxially to one another and in axial succession. A movable magnet system with a plurality of axially consecutive permanent magnets is formed in the axial direction relative to the winding system. The winding system is fed by a controlled converter.

DE 10 2016 121 674 A1 deals with the problem that outgassing can occur in lines running inside process chambers under vacuum. This leads to foreign material contamination and/or particle contamination of the vacuum and thus to a deterioration in the vacuum quality, which can affect the processing results of a corresponding component. To avoid problems of the type described, it is proposed there to combine a first transaction permanent magnet device, which is attached to a frame, with a rotary permanent magnet device, which is provided on a bogie. Longitudinal guide means are also provided.

A generic device for holding, positioning and moving an object by means of a magnetic bearing and linear motor is described in DE 10 2015 004 582A1. The drive there consists of a linear motor with at least one stator and one slider, which are arranged on a base there and on a carrier. The linear motor for moving the carrier along the base not only generates a displacement force in the direction of movement or transport direction, but also a counterforce that counteracts a magnetic position present there. The magnetic bearing is designed as a vertical magnetic bearing for weight compensation and for holding the carrier in a floating, contactless position, so that improved lateral stabilization of the carrier can be achieved.

What the known solutions have in common is that there are still contact and contact points of moving connecting bearings and machine elements or corresponding joints. This means that all surfaces in contact with the vacuum lead to unavoidable particle contamination and outgassing effects.

From the foregoing, it is therefore the object of the invention to provide a further developed device for holding, positioning and/or moving an object in a process vacuum, which avoids or minimizes particle generation on the vacuum side.

The solution to the object of the invention is provided by the device in the combination of features according to claim 1, wherein the sub-claims represent at least useful embodiments and further developments.

A device for holding, positioning and/or moving an object, e.g. a semiconductor substrate in a process vacuum, is therefore assumed.

The device comprises a base, an end effector with substrate holder and a linear drive coupled to the end effector via a carriage.

There is also a vertical or lifting drive at the base which acts on the latter. In addition, a magnetic bearing is used for the aforementioned carriage.

According to the invention, the linear drive is designed as a cylinder which can be pressurized with a fluid, in particular a gas, but is otherwise closed, having a double-acting piston arranged movably in the cylinder.

The piston is equipped with a magnet arrangement.

Furthermore, the carriage has a magnetic ring which engages around the outside of the cylinder, at least in sections, and which surrounds the cylinder without contact.

The carriage can be moved in a non-contacting translatory manner in relation to the base and is also magnetically guided to prevent rotational tilting.

In terms of design, the base with linear drive and end effector is connected to a lifting drive. A shaft with bearing connected to the base is provided for this purpose.

The shaft can be rotated around its axis by means of a magnetic rotary coupling and can be locked in relation to the rotation or pivot angle.

The aforementioned shaft is preferably designed as a hollow shaft. The fluid for moving the piston in the cylinder of the linear drive can be fed in and out via corresponding channels in the shaft.

At least the base with end effector and substrate holder, linear drive and magnetic guide are located in the process vacuum, wherein a particle generation below a surface cleanliness class of 10,000, an accumulated molecular contamination of heavy hydrocarbons of less than 10 μg/cm2 and an outgassing rate of less than 2E-9 mbar·I/(s·cm2) is maintained.

The carriage and the magnetic ring can be monolithic or in one piece. In addition, a linear magnetic constraint guide is provided to prevent rotational tilting.

In one embodiment of the invention, a balancing weight is arranged at the end opposite the substrate holder.

The lifting drive is located on the atmospheric side facing away from the process vacuum.

The magnetic ring can be designed as a ring cylinder with a plurality of magnetic sections.

The piston is sealed against the cylinder interior or cylinder inner wall by means of elastic elements located in annular grooves.

Undesirable particle generation is reduced to a minimum, in particular due to the rodless cylinder design together with the piston to which the fluid is applied and the aforementioned magnet carriage. The desired translational displacement of the substrate holder is made possible by the magnet carriage, wherein rotational tilting is avoided by an additional linear magnetic constraint guide.

In comparison with the prior art, one of the basic ideas of the present invention is to move a double-acting piston driven by a fluid in a cylinder closed on all sides and acted upon by the fluid, the movement of which is transmitted via a magnetic force coupling to a ring surrounding the cylinder externally without contact for the purpose of generating the linear movement.

The invention will be explained in more detail below with reference to an exemplary embodiment and with the aid of figures.

The drawings show as follows:

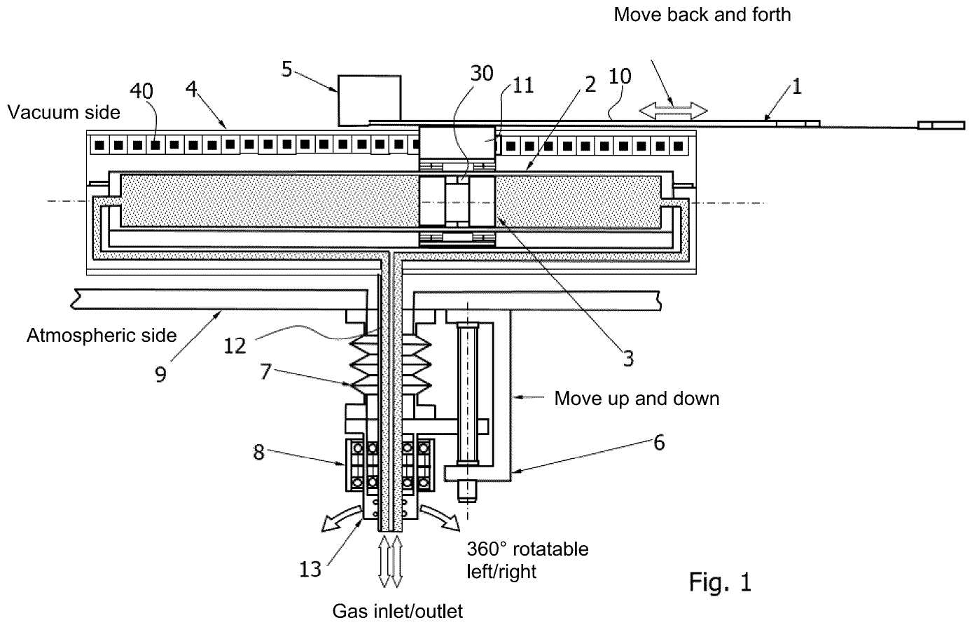

FIG. 1 shows a lateral sectional view of the device according to the invention with substrate holder or end effector, the pneumatic cylinder together with piston and magnet as well as recognizable magnetic guide and the lifting device for generating a vertical movement;

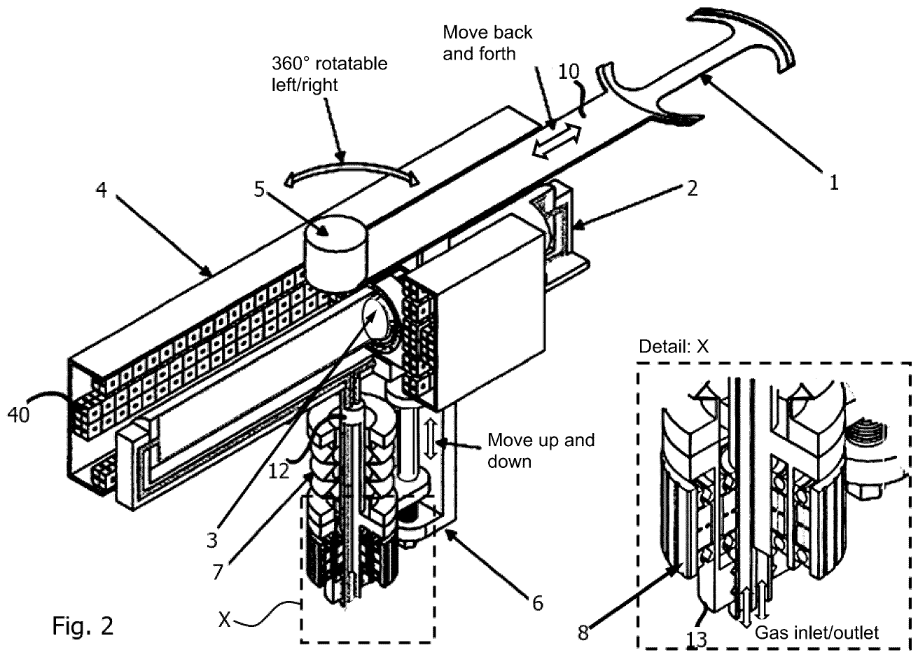

FIG. 2 shows a perspective view (part cut away) of the device according to the invention analogous to FIG. 1 with details with regard to the magnetic guidance of the linear drive and the magnetic rotary coupling (right part of the image according to FIG. 2) and

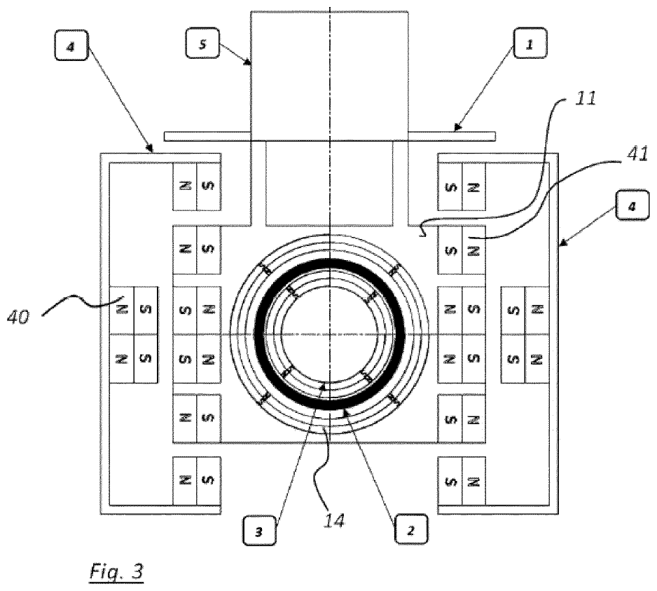

FIG. 3 shows a sectional view of the cylinder and piston of the linear drive with the elements of the magnetic guide.

The device for holding, positioning and/or moving an object, e.g. a substrate, in a process vacuum starts from a base 4 which has a magnetic guide 40 in its interior.

An end effector 10 with a substrate holder 1 at one of its ends can be moved translationally and rotationally and is guided in the base 4.

There is a counterweight 5 at the end opposite the carriage or substrate holder 1.

The actual linear actuator comprises a pneumatic cylinder 2 inside the base 4 with magnetic guide 40.

The pneumatic cylinder 2 has a double-acting, movable piston 3 in its interior, which comprises magnets 30 in the piston 3.

As can be seen in particular in FIG. 3, there is a carriage on the outside of the cylinder 2 in the form of a magnet carriage 11.

The carriage is coupled to the end effector and thus to the substrate holder 1.

The interaction of the magnets 30 in the piston with the magnets of the carriage 11 transmits the movement of the piston 3 to the carriage 11 without contact.

Further guidance and protection against rotational tilting is achieved via the magnet arrangement 40 at the base and 41 in the area of the carriage.

To generate a vertical movement of the base together with the linear drive, a lifting device 6 is provided, which is located outside the process vacuum on the atmospheric side.

Part of a vacuum chamber is indicated by the reference sign 9.

The connection between the linear drive and the lifting device 6 is made via a shaft 12.

As shown in FIGS. 1 and 2 and the detailed illustration in FIG. 2, the shaft 12 is designed as a hollow shaft and has channels for supplying and discharging the fluid for moving the piston via a gas inlet or gas outlet.

A rotary coupling (see FIG. 2/detail illustration) enables rotation or pivoting as shown by the arrow in FIG. 2.

A bellows 7, which is variable in length, surrounds the shaft 12 on the outside.

The shaft is guided at the end and a seal 13 is formed.

1. Device for holding, positioning and/or moving an object in a vacuum, comprising a base (4) having an end effector (10) with substrate holder (1), a linear drive coupled to the end effector (10) via a carriage (11) and a magnetic bearing for the carriage (11),
characterized in that
the linear drive is designed as a cylinder (2) which can be pressurized by a fluid and is otherwise closed, having a double-acting piston (3), wherein the piston (3) is provided with a magnet arrangement (30), furthermore the carriage (11) has a magnetic ring (14) which engages around the cylinder (2) at least in sections on the outside and which surrounds the cylinder (2) without contact, and the carriage (11) can be moved in translation without contact relative to the base (4) and is secured against rotational tilting and is guided magnetically (40; 41).

2. Device according to claim 1,
characterized in that
the base (4) with linear drive and end effector (10) is connected to a vertical or lifting drive, in particular a lifting drive (6), and a shaft (12) with seal (13) connected to the base (4) is formed for this purpose.

3. Device according to claim 2,
characterized in that
the base (4) can be rotated and locked about the axis of the shaft (12) via the shaft (12) by means of a magnetic rotary coupling (8).

4. Device according to claim 2,
characterized in that
the shaft (12) is designed as a hollow shaft and has channels for supplying and discharging the fluid for moving the piston (3) in the cylinder (2) of the linear drive.

5. Device according to claim 1,
characterized in that
at least the base (4) with end effector (10) and substrate holder (1), linear drive and magnetic guide are located in the process vacuum, wherein a particle generation below a surface cleanliness class of 10,000, an accumulated molecular contamination of heavy hydrocarbons of less than 10 μg/cm2 and an outgassing rate of less than 2E-9 mbar·1/ (s·cm2) is maintained.

6. according to claim 1,
characterized in that
the carriage (11) and the magnetic ring (14) are formed in one piece and are additionally secured against rotational tilting by means of a linear magnetic constraint guide.

7. Device according to claim 1,
characterized in that
a balancing weight body (5) can be arranged at the end opposite the substrate holder (1).

8. Device according to claim 2,
characterized in that
the lifting drive (6) is optionally located on the atmospheric side facing away from the vacuum.

9. Device according to claim 1,
characterized in that
the magnetic ring (14) is designed as a ring cylinder with a plurality of magnetic sections.

10. Device according to claim 1,
characterized in that
the piston (3) is sealed against the cylinder inner wall by means of elastic elements located in annular grooves.
